(19) United States
(12) Patent Application Publication
(10) Pub. No.: US 2025/0232828 A1
(43) Pub. Date: Jul. 17, 2025

(54) 3-DIMENSIONAL SEMICONDUCTOR MEMORY DEVICE AND A METHOD OF OPERATING THE 3-DIMENSIONAL SEMICONDUCTOR MEMORY DEVICE

(71) Applicant: SAMSUNG ELECTRONICS CO., LTD., Suwon-si, Gyeonggi-do (KR)

(72) Inventors: Myeong-Woo Lee, Suwon-si (KR); Sang-Won Park, Suwon-si (KR); Woobin Park, Suwon-si (KR)

(21) Appl. No.: 18/793,563

(22) Filed: Aug. 2, 2024

(30) Foreign Application Priority Data
Jan. 17, 2024 (KR) 10-2024-0007320

(51) Int. Cl. G11C 29/12; G11C 29/44; H01L 23/00; H01L 25/065; H01L 25/18; H10B 80/00

(52) U.S. Cl. CPC G11C 29/12005; G11C 29/44; H01L 24/08; H01L 25/0657; H01L 25/18; H10B 80/00; G11C 2029/1204; H01L 2224/08145; H01L 2924/1431; H01L 2924/14511

(57) ABSTRACT

A 3-dimensional semiconductor memory device includes a cell array structure including a first substrate, a common source line disposed on the first substrate, a plurality of conductive lines stacked in a first direction vertical to an upper surface of the first substrate on the common source line, a channel structure extending through the plurality of conductive lines and connected to the common source line, a bit line connected to the channel structure, and a first bonding metal electrically connected to the bit line, and a peripheral circuit structure including a second bonding metal in contact with the first bonding metal, a page buffer, and a row decoder.

### CROSS-REFERENCE TO RELATED APPLICATION

This application claims priority to Korean Patent Application No. 10-2024-0007320, filed in the Korean Intellectual Property Office on Jan. 17, 2024, the disclosure of which is incorporated by reference in its entirety.

### BACKGROUND

As an amount of a data that electronic devices process increases, high-capacity and high-bandwidth memory devices are desired. To improve the integration of the semiconductor memory, fine processes and 3-dimensional stacking technologies are being used in the semiconductor memory devices.

As the above processes and technologies are applied, defects may occur inside the semiconductor memory chip. Since these defects cause erroneous operations of the semiconductor memory chip, tests may be conducted to detect whether the defect occurred and the cause of the defect.

Among the types of the defects, there are progressive defects that are not initially defective, but device characteristics change over time due to process problems, resulting in permanent failure. The progressive defects are no or little problem during the testing, but the defect appears when the user uses the electronic devices. For the progressive defects, a stress is generally applied during the testing to detect the defects early and repair the detected defective components.

### SUMMARY

In general, in some aspects, the present disclosure is directed toward a 3-dimensional semiconductor memory device and an operation method of the 3-dimensional semiconductor memory device that detects progressive defects in a bonding area within the 3-dimensional stacking structure early and prevents data that cannot be restored from occurring, and a 3-dimensional semiconductor memory device and an operation method of the 3-dimensional semiconductor memory device that detects progressive defects in a bit line early and prevents unrestored data from occurring.

According to some implementations, the present disclosure is directed to a 3-dimensional semiconductor memory device including a cell array structure including a first substrate, a common source line disposed on the first substrate, a plurality of conductive lines stacked in a first direction vertical to an upper surface of the first substrate on the common source line, a channel structure extending through the plurality of conductive lines and connected to the common source line, a bit line connected to the channel structure, and a first bonding metal electrically connected to the bit line; and a peripheral circuit structure including a second bonding metal in contact with the first bonding metal, a page buffer configured to provide a first stress voltage to the bit line through the second bonding metal in response to a pass voltage being applied to the plurality of conductive lines, and a row decoder configured to provide a second stress voltage with a different voltage level from the first stress voltage to the common source line in response to providing the first stress voltage.

According to some implementations, the present disclosure is directed to a 3-dimensional semiconductor memory device including a memory cell array including a plurality of cell strings, a first cell string of the plurality of cell strings includes a plurality of first memory cells connected to a first bit line and a second cell string of the plurality of cell strings includes a plurality of second memory cells connected to a second bit line different from the first bit line, and a common source line connected to the first cell string and the second cell string, a row decoder configured to apply an erase voltage to the common source line, and a page buffer configured to apply an erase voltage to the first bit line and a ground voltage to the second bit line in response to the application of the erase voltage to the common source line.

According to some implementations, the present disclosure is directed to An operation method of a 3-dimensional semiconductor device including applying a pass voltage to a plurality of gate lines stacked in a vertical direction to an upper surface of a substrate, applying a first stress voltage to a common source line extending between the substrate and the plurality of gate lines, and applying a second stress voltage, different from the first stress voltage, to a bit line connected to a channel structure that extends through the plurality of gate lines in response to the application of the pass voltage, detecting defects for each bit line after applying the first stress voltage and the second stress voltage, and performing a repair operation based on a result of the detecting defects.

### BRIEF DESCRIPTION OF THE DRAWINGS

Example implementations will be more clearly understood from the following detailed description, taken in conjunction with the accompanying drawings.

FIG. 1 is a block diagram showing an example of a storage system according to some implementations.

FIG. 2 is a block diagram showing an example of a non-volatile memory device according to some implementations.

FIG. 3 is a circuit diagram showing an example of a page buffer according to some implementations.

FIG. 4 is a diagram illustrating an example of a memory block according to some implementations.

FIG. 5 is a circuit diagram showing examples of cell string and a page buffer according to some implementations.

FIG. 6 is a perspective view showing an example of a non-volatile memory device according to some implementations.

FIG. 7 is a cross-sectional view showing an example of a non-volatile memory device taken along a line C-C′ of FIG. 6 according to some implementations.

FIG. 8 is an enlarged view of an example of a bonding area BA of FIG. 7 according to some implementations.

FIG. 9 is a flowchart illustrating an example of an operation method of a non-volatile memory device according to some implementations.

FIG. 10 is a flowchart illustrating an example of an operation method of a non-volatile memory device according to some implementations.

FIG. 11 is a timing diagram illustrating an example of an operation method of a non-volatile memory device according to some implementations.

FIG. 12 is a circuit diagram showing examples of a cell string, a bit line, and a page buffer according to an operation of a non-volatile memory device according to some implementations.

FIG. 13 is a timing diagram showing an example of an operation method of a non-volatile memory device according to some implementations.

FIG. 14 is a circuit diagram showing examples of a cell string, a bit line, and a page buffer according to an operation of a non-volatile memory device according to some implementations.

FIG. 15 is a flowchart illustrating an example of an operation method of a non-volatile memory device according to some implementations.

FIG. 16 is a timing diagram showing an example of an operation method of a non-volatile memory device according to some implementations.

FIG. 17 is a circuit diagram showing examples of a cell string, a bit line, and a page buffer according to an operation of a non-volatile memory device according to some implementations.

FIG. 18 is a block diagram showing an example of an electron system including a non-volatile memory device according to some implementations.

### DETAILED DESCRIPTION

Hereinafter, example implementations will be described in detail with reference to the accompanying drawings. Like reference numerals designate like elements throughout the specification.

In the drawings, a size and thickness of each element are randomly represented for better understanding and ease of description, and the present disclosure is not limited thereto. In the drawings, the thickness of layers, films, panels, areas, etc., are exaggerated for clarity, and, for better understanding and ease of description, the thicknesses of some layers and areas are exaggerated.

Further, it will be understood that when an element such as a layer, film, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Additionally, a specific number stated in a claim, even if explicitly cited within the claim, should not be construed as limiting the specific number in a claim where such citation does not exist. For example, to aid an understanding, subsequent dependent claims could include phrases ‘at least one’ and ‘one or more’. However, the use of such a phrase should not be understood as a limitation described by the unclear article ‘one’ for the sake of one example.

Additionally, when the conventions such as ‘at least one of A, B, or C’ are used, these phrases will be well understood by those skilled in the art (i.e., ‘a system including at least one of A, B, or C’ includes means of A alone, B alone, C alone, A and B, A and C, B and C, and/or A, B and C together, but it is not limited to any one concept). Letters and/or phrases including two or more separate selectable terms in the detailed description, or claims or drawings should be considered as possible to include one, or either, or both terms. For example, the phrase ‘A or B’ should be understood as including the possibilities ‘A’, or ‘B’ or ‘A and B’.

Terms such as “module,” “unit,” and “part” used in this document refer to a component that performs at least one function or operation, and such component may be implemented as a hardware or a software, or may be implemented by combining a hardware and a software.

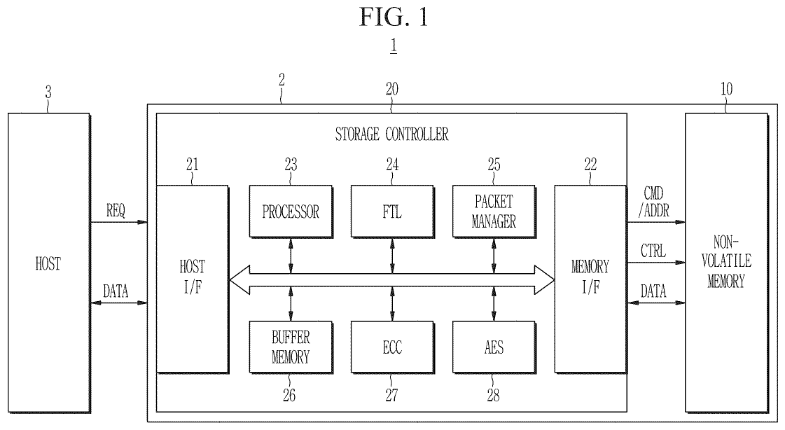

FIG. 1 is a block diagram showing an example of a storage system according to some implementations. In FIG. 1, a storage system 1 may include a host 3 and a storage device 2. The storage device 2 may include a storage medium for storing a data DATA according to a request REQ from the host 3. For example, the storage device 2 may include any one such as a solid state drive (SSD), a built-in memory, and a removable external memory, or a combination thereof. If the storage device 2 is equipped with the SSD, the storage device 200 may be a device that complies with standards such as a non-volatile memory express (NVMe), a serial ATA (SATA), and a serial attached SCSI (SAS). If the storage device 2 is provided with the built-in memory or the external memory, the storage device 2 may be a device that complies with standards such as a universal flash storage (UFS), an embedded multi-media card (eMMC), a security digital (SD), or another protocol. The host 3 and the storage device 2 may each generate and transmit packets according to the adopted standard protocol.

The storage device 2 may include a storage controller 20 and a non-volatile memory device 10. Each of the storage controller 20 and the non-volatile memory device 10 may be provided as one chip, one package, one module, etc. In some implementations, the storage controller 20 and the non-volatile memory device 10 may be mounted based on various packages and provided as a storage device such as a memory card.

The non-volatile memory device 10 may include a flash memory. For example, the flash memory may include a 3-dimensional (or vertical) NAND (VNAND) memory array.

The storage controller 20 may include a host interface 21, a memory interface 22, and a processor 23. In addition, the storage controller 20 may further include a flash translation layer (FTL) 24, a packet manager 25, a buffer memory 26, an error correction code (ECC) engine 27, and an advanced encryption standard (AES) engine 28.

The host interface 21 may transmit the packets to the host 3 and receive the packets from the host 3. The packet transmitted from the host 3 to the host interface 21 may include commands, a data to be programmed in the non-volatile memory device 10, etc. The packet transmitted from the host interface 21 to the host 3 may include a response for the request REQ, the data DATA read from non-volatile memory device 10, etc.

The memory interface 22 may transmit the data to be programmed in the non-volatile memory device 10 to the non-volatile memory device 10, or receive the data read from the non-volatile memory device 10. The memory interface 22 may be implemented to follow standard conventions, such as Toggle or ONFI.

In response to the request REQ of the host 3 and the data DATA, the storage controller 20 may output a command CMD and/or an address ADDR, a control signal CTRL, and the data DATA through the memory interface 22.

The non-volatile memory device 10 according to the embodiment may receive the control signal CTRL from the storage controller 20 to apply a stress voltage to some components and detect defects expressed by the stress voltage. The non-volatile memory device 10 according to some implementations may perform a repair operation according to the result of the defect detection.

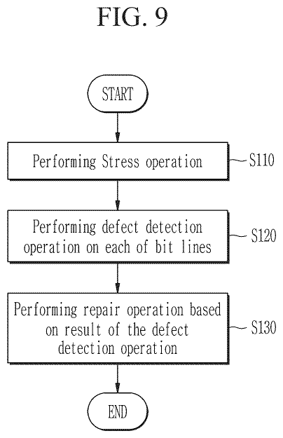

Hereinafter, the operation in which the non-volatile memory device 10 applies the stress voltage to some components to cause defects is referred to as ‘a stress operation’. The detailed explanation of the stress operation is described with reference to FIG. 9 to FIG. 17 below.

According to some implementations, the FTL 24 may be loaded into a working memory (not shown). The working memory may be operated under the control of the processor 23 and may be used as a working memory, a buffer memory, a cache memory, etc. For example, the working memory may be implemented as a volatile memory such as DRAM and SRAM, or a non-volatile memory such as PRAM and a flash memory. According to some implementations, the FTL 24 may be a dedicated circuit.

The FTL 24 may control data programming and read operations for non-volatile memory device 10. The FTL 24 may perform a variety of functions such as an address mapping, a wear leveling, and a garbage collection. The address mapping operation is an operation that converts the logical address received from the host 3 into a physical address used to actually store the data DATA in the non-volatile memory device 10. The wear leveling function is a technology that prevents excessive degradation of specific blocks by uniformly using blocks of the non-volatile memory device 10. For example, the wear leveling may be implemented through firmware techniques that balance the number of erases of the physical blocks. The garbage collection function is a technology that secures the available capacity of the non-volatile memory device 10 by copying a valid data of a block to a new block and erasing the existing block.

The packet manager 25 may generate a packet according to the protocol of the interface negotiated with the host 3 or parse various information from the packet received from the host 3. Additionally, the buffer memory 26 may temporarily store the data DATA to be programmed in the non-volatile memory device 10 or the data DATA read from the non-volatile memory device 10. The buffer memory 26 may be provided inside the storage controller 20, or may be provided outside the storage controller 20.

The ECC engine 27 may perform an error detection and a correction functions for the data DATA read from the non-volatile memory device 10. More specifically, the ECC engine 27 may generate parity bits for the data to be programmed in the non-volatile memory device 10, and the generated parity bits may be stored in the non-volatile memory device 10 together with the write data. When the data DATA is read from the non-volatile memory device 10. The ECC engine 27 may correct the error in the read data by using the parity bits read from the non-volatile memory device 10 together with the read data and output the read data of which the errors are corrected.

The AES engine 28 may perform any one or any combination of an encryption or a decryption on the data input to the storage controller 20 by using a symmetric-key algorithm.

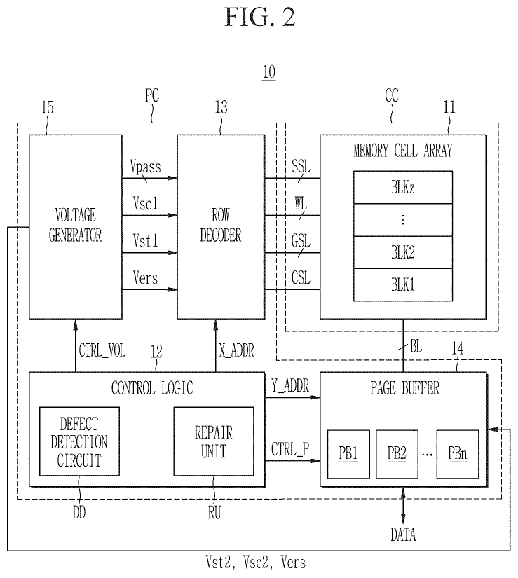

FIG. 2 is a block diagram showing an example of a non-volatile memory device according to some implementations. In FIG. 2, the non-volatile memory device 10 may include a memory cell circuit CC and a peripheral circuit PC. The memory cell circuit CC may include a memory cell array 11. The peripheral circuit PC may include a circuit to operate the memory cell array 11.

The peripheral circuit PC may include a control logic 12, a row decoder 13, a page buffer 14, and a voltage generator 15. In some implementations, the peripheral circuit PC may further include a column logic, a free-decoder, temperature sensor, a command decoder, an address decoder, the like.

The memory cell array 11 may be connected to the page buffer 14 through a bit line BL, and to a row decoder 13 through a plurality of word lines WL, a plurality of string selection lines SSL, a plurality of ground selection lines GSL, and a common source line CSL.

The memory cell array 11 may include a plurality of memory blocks (BLK1 to BLKz, hereinafter z is an integer of 2 or more) including a plurality of memory cells. For example, the memory cells may be flash memory cells. Hereinafter, some implementations of the present disclosure will be described as an example in which the plurality of memory cells are the NAND flash memory cells. However, the present disclosure is not limited to this, and in some implementations, and the plurality of memory cells may be resistive memory cells, such as a resistive RAM (ReRAM), a phase change RAM (PRAM), a ferroelectric RAM (FRAM) or a magnetic RAM (MRAM).

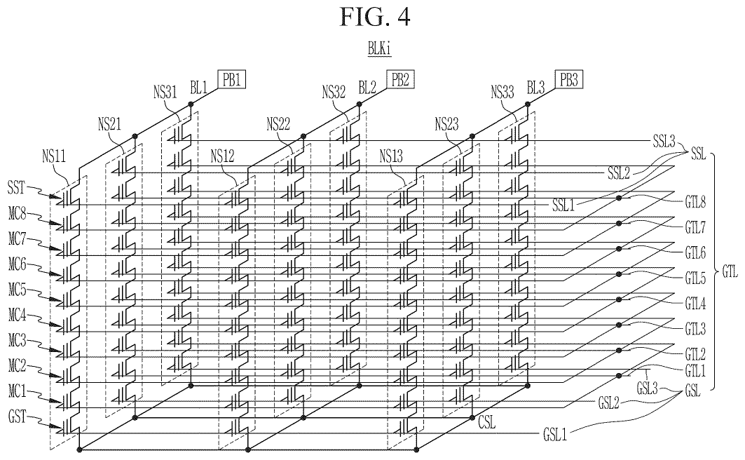

In some implementations, the memory cell array 11 may include a 3-dimensional memory cell array, and the non-volatile memory device 10 may be referred to as a 3-dimensional semiconductor memory device. The 3-dimensional memory cell array may include a plurality of cell strings, and each cell string may include the memory cells each connected to a plurality of word lines stacked vertically on the substrate. The detailed description of the structure of the 3-dimensional memory cell array is explained below in the explanation of FIG. 4 to FIG. 8.

The control logic 12 may include a defect detection circuit DD and a repair unit RU. The control logic 12 may output various control signals to operate the non-volatile memory device 10 based on the command CMD, the address ADDR, and the control signal CTRL of FIG. 1. The control logic 12 may output control signals to write or program the data DATA to the memory cell array 11, or to read the data DATA from the memory cell array 11, or to erase the data stored in the memory cell array 11, or apply the stress voltage to some components. For example, the control logic 12 may output a voltage control signal CTRL_vol, a page buffer control signal CTRL_P, a row address X-ADDR, and a column address Y-ADDR.

The defect detection circuit DD according to some implementations may generate signals to control the plurality of page buffers PB1 to PBn and/or the row decoder 13. As an example, the defect detection circuit DD may generate the control signals so that the plurality of page buffers PB1 to PBn and the row decoder 13 are controlled based on different control timings. The defect detection circuit DD may detect defects for each bit line based on the different control timing. According to some implementations, the defect detection circuit DD may detect an operation abnormality for the bit line implemented with the stress voltage.

According to some implementations, the repair unit RU may perform a repair operation on the bit line BL based on the detection result of the defect detection circuit DD. As an example, if the defect detection circuit DD detects the operation abnormality for one bit line, the repair unit RU may perform the repair operation for one bit line and provide the page buffer control signal CTRL_P to the page buffer 14. Through the repair operation of the repair unit RU, the bit line that operates erroneously due to the defect that appears may be replaced with a new bit line.

The page buffer 14 may include a plurality of page buffers PB1 to PBn, and each of the plurality of page buffers PB1 to PBn may be connected to each of the memory cells through the bit line BL. The page buffer 14 may select at least one bit line among the bit lines BL according to the column address Y-ADDR and the page buffer control signal CTRL_P provided in the control logic 12.

During the program operation, the page buffer 14 may apply the program bit line voltage corresponding to the data DATA to be programmed to the selected bit line. During the read operation, the page buffer 14 may detect the data DATA stored in the memory cell by detecting the current or the voltage through the selected bit line. The page buffer 14 may temporarily store the data DATA to be programmed or the data DATA read from the memory cell. By way of example, the plurality of page buffers PB1 to PBn may each include one or more data latches. The data latches may temporarily store the data DATA.

According to some implementations, the plurality of page buffers PB1 to PBn may each include one or more transistors and one or more data latches related to the operations for temporarily storing the data. For example, the plurality of page buffers PB1 to PBn each may perform a pre-charge operation for the bit line BL based on the switching operation of one or more transistors. In addition, as a sensing node and the bit line BL are electrically connected based on the switching operation of one or more transistors, each of the plurality of page buffers PB1 to PBn may sense the data DATA through the sensing node.

In addition, based on the switching operation of transistors, the data stored in one data latch may be moved to another latch, and the data DATA to be written may be provided to the memory cell array 11 through the bit line BL, or the read data DATA may be provided to the outside of the non-volatile memory device 10 through the bit line BL.

According to some implementations, the page buffer 14 may apply the erase voltage Vers to the bit line BL during the erase operation. The page buffer 14 according to the embodiment may apply the erase voltage Vers from the bit line BL to the common source line CSL direction in response to the erase voltage Vers being applied from the common source line CSL toward the bit line BL during the erase operation.

According to some implementations, the page buffer 14 may provide the second stress voltage Vst2 to the bit line BL during the stress operation. According to some implementations, the second stress voltage Vst2 may have a different voltage level from the first stress voltage Vst1 provided to the common source line CSL. According to some implementations, the second stress voltage Vst2 may be the erase voltage Vers, or a ground voltage. For example, if the second stress voltage Vst2 is the erase voltage Vers, the first stress voltage Vst1 may be the ground voltage, and if the second stress voltage Vst2 is the ground voltage, the first stress voltage Vst1 may be the erase voltage Vers.

According to some implementations, during the stress operation, the page buffer 14 may provide the second stress voltage Vst2 for each bit line BL based on the data stored in the data latch. As an example, the page buffer 14 may apply the erase voltage Vers to one bit line and the ground voltage to another bit line based on the data stored in the data latch during the stress operation.

The row decoder 13 may select one of the plurality of memory blocks BLK1 to BLKz in response to the row address X-ADDR, select one of the word lines WL of the selected memory block, and select one plurality of string selection lines SSL. The page buffer 14 may select some of the bit lines BL in response to the column address Y-ADDR. Specifically, the page buffer 14 may operate as a write driver or sense amplifier depending on the operation mode.

According to some implementations, the row decoder 13 may apply the erase voltage Vers to the common source line CSL during the erase operation. The row decoder 13 according to an embodiment may apply the erase voltage Vers from the common source line CSL to the bit line BL direction in response to the erase voltage Vers being applied from the bit line BL toward the common source line CSL during the erase operation.

According to some implementations, the row decoder 13 may provide the first stress voltage Vst1 to the common source line CSL during the stress operation. According to some implementations, the first stress voltage Vst1 may have a different voltage level from the second stress voltage Vst2 provided to the bit line BL. According to some implementations, the first stress voltage Vst1 may be the erase voltage Vers, or the ground voltage. As an example, if the first stress voltage Vst1 is the erase voltage Vers, the second stress voltage Vst2 may be the ground voltage, and if the first stress voltage Vst1 is the ground voltage, the second stress voltage Vst2 may be the erase voltage Vers.

According to some implementations, during the stress operation, the row decoder 13 may apply a pass voltage Vpass to the entire plurality of word lines WL, the string selection line SSL, and the plurality of ground selection lines GSL. According to some implementations, the pass voltage Vpass may be a voltage applied to an unselected word line during the read operation for the memory cell array 11.

The voltage generator 15 may generate various types of voltages to perform the program, the read, the erase operation, and the stress operation for the memory cell array 11 based on the voltage control signal CTRL_vol. According to some implementations, the voltage generator 15 may generate a word line voltage, for example, a program voltage, a read voltage, a pass voltage, an erase verification voltage, or a program verification voltage, etc. According to some implementations, voltage generator 15 may generate word line voltage, for example, program voltage, read voltage, pass voltage, erase verify voltage or program verify voltage. In addition, the voltage generator 15 may further generate a string selection line voltage, a ground selection line voltage, the erase voltage Vers applied to the common source line CSL based on the voltage control signal CTRL_vol. Additionally, according to some implementations, the voltage generator 15 may generate one or more voltages to drive or control the page buffer 14, and may illustratively generate the erase voltage Vers and to be provided to the page buffer 14.

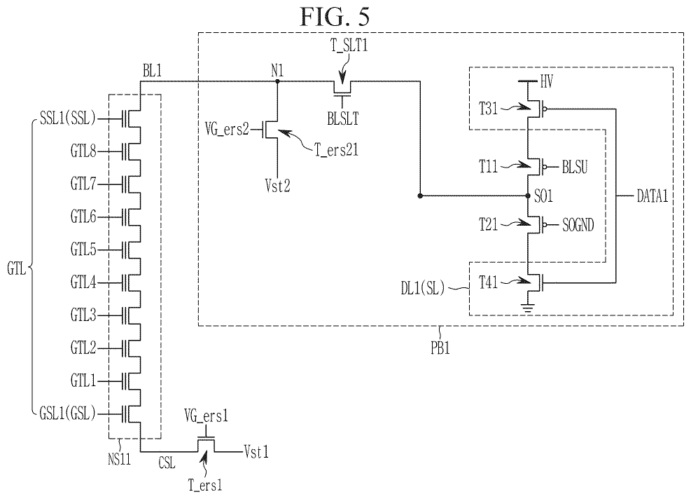

According to some implementations, the voltage generator 15 may provide the first stress voltage Vst1 and the first stress control voltage Vsc1 for the stress operation to the row decoder 13. The row decoder 13 may include one or more transistors related to the stress operation, and the row decoder 13 may receive the first stress control voltage Vsc1 from the voltage generator 15 to control the switching operation for the one or more transistors. The row decoder 13 may provide the first stress voltage Vst1 to the common source line CSL through the switching operation, and apply the pass voltage Vpass to all of the plurality of word lines WL, the string selection line SSL, and the plurality of ground selection lines GSL during the stress operation. As an example, the row decoder 13 may receive the first stress control voltage Vsc1 to control the switching operation of the first erase transistor T_ers1 of FIG. 5.

According to some implementations, the voltage generator 15 may provide the second stress voltage Vst2 and the second stress control voltage Vsc2 for the stress operation to the page buffer 14. The page buffer 14 may include one or more transistors related to the stress operation, and the page buffer 14 may receive the second stress control voltage Vsc2 from the voltage generator 15 to control the switching operation for the one or more transistors. The page buffer 14 may provide the second stress voltage Vst2 to the bit line BL through the switching operation. For example, the page buffer 14 may receive the second stress control voltage Vsc2 to control the switching operation of the second_first erase transistor T_ers21, the first bit line selection transistor T_SLT1, the first_first transistor T11, and the first_second transistor T12 of FIG. 5.

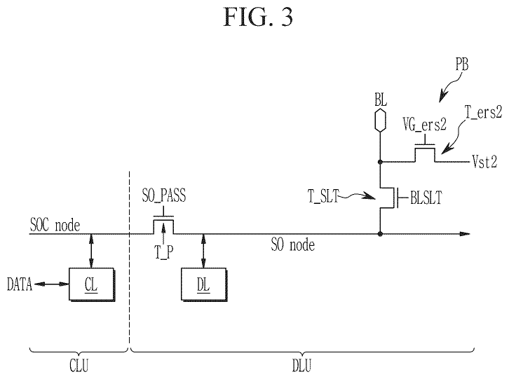

FIG. 3 is a circuit diagram showing an example of a page buffer according to some implementations. In FIG. 3, the page buffer PB may include a cache latch unit CLU and a data latch unit DLU. The page buffer PB may correspond to one of the plurality of page buffers PB1 to PBn in FIG. 2.

The cache latch unit CLU may include a cache latch CL. For example, the cache latch CL may store the data DATA to be written to the memory cell. Additionally, the cache latch CL may store the data DATA transmitted from the data latch DL. The cache latch CL can be connected to a coupled sensing node SOC. The cache latch CL may transmit and receive the data DATA through the cache latch node SOC, in the drawing, one cache latch CL is shown to be placed in the cache latch unit CLU, but it may include two or more cache latches CLs. The cache latch node SOC may be connected to the sensing node SO through the pass transistor T_P.

The data latch unit DLU may include a pass transistor T_P, a data latch DL, a bit line selection transistor T_SLT, and a second erase transistor T_ers2.

The pass transistor T_P may be turned on or turned off depending on the pass signal SO_PASS. When the pass transistor T_P is turned on, the data DATA may be transmitted between the cache latch CL and the data latch DL.

According to some implementations, the data latch DL is connected to the sensing node SO and may store the data DATA transmitted from the cache latch CL. Additionally, the data latch DL may store the data DATA read from the memory cell and transmit the data DATA to the cache latch CL. In FIG. 3, one data latch DL is shown to be placed in the data latch unit DLU, but it may include two or more data latches DL.

The sensing node SO may be pre-charged during the read or program operation of the non-volatile memory device 10. The sensing node SO may be connected to the bit line BL through the bit line selection transistor T_SLT. For example, the bit line selection transistor T_SLT may be connected between a connection node N connected to the bit line BL and the sensing node SO. The bit line selection transistor T_SLT may be turned on or turned off depending on the bit line selection signal BLSLT. According to some implementations, the bit line selection transistor T_SLT may be an NMOS transistor, but it is not limited thereto.

One end of the second erase transistor T_ers2 may be connected to the connection node N, which is connected to the bit line BL. The second erase transistor T_ers2 may be turned on or turned off depending on the second erase control signal VG_ers2. According to some implementations, the second erase transistor T_ers2 may be an NMOS transistor, but it is not limited thereto.

During the erase operation, the second erase transistor T_ers2 may be turned on and provide the erase voltage to bit line BL through the connection node N.

According to some implementations, during the stress operation, the second erase transistor T_ers2 may be turned on and provide the second stress voltage Vst2 to the bit line BL through the connection node N. If the second erase transistor T_ers2 is turned on during the stress operation, the bit line selection transistor T_SLT may be turned off.

According to some implementations, during the stress operation, the bit line selection transistor T_SLT may be turned on so that the second stress voltage Vst2 can be applied to the bit line BL through connection node N based on the data latched in the data latch DL. One end of the bit line selection transistor T_SLT may be connected to the connection node N, which is connected to the bit line BL. If the bit line selection transistor T_SLT is turned on during the stress operation, the second erase transistor T_ers2 may be turned off.

During the stress operation, the second erase transistor T_ers2 and the bit line selection transistor T_SLT may be operated complementary to each other. As an example, when the second erase transistor T_ers2 is turned on, the bit line selection transistor T_SLT may be turned off, and when the bit line selection transistor T_SLT is turned on, the second erase transistor T_ers2 may be turned off.

FIG. 4 is a diagram illustrating an example of a memory block according to some implementations. The memory block BLK1 of FIG. 4 may be an equivalent circuit for one among the plurality of memory blocks BLK1 to BLKz of FIG. 1.

In FIG. 4, the memory block BLK1 represents a 3-dimensional memory block formed in a three-dimensional structure on a substrate. For example, the plurality of cell strings included in the memory block BLK1 may be formed in a direction vertical to the substrate.

The memory block BLK1 may include a plurality of cell strings NS11 to NS33 connected between the plurality of bit lines BL1, BL2, and BL3 and the common source line CSL. Each of the plurality of cell strings NS11 to NS33 may include a string selection transistor SST, a plurality of memory cells MC1, MC2, . . . , MC8, and a ground selection transistor GST. The plurality of cell strings NS11 to NS33 may be connected to the plurality of gate lines GTL. The string selection transistor SST, the plurality of memory cells MC1, MC2, . . . , MC8, and the ground selection transistor GST may be connected to the corresponding string selection line SSL among the plurality of gate lines GTL, the memory cell gate lines GTL1, GTL2, . . . , GTL8, and the ground selection line GSL.

In FIG. 4, each of the plurality of cell strings NS11 to NS33 are shown to include eight memory cells MC1, MC2, . . . , MC8, but are not necessarily limited thereto.

The string selection transistor SST may be connected to the corresponding string selection lines SSL1, SSL2, and SSL3. The plurality of memory cells MC1, MC2, . . . , MC8 may be connected to the corresponding memory cell gate lines GTL1, GTL2, . . . , GTL8, respectively. The memory cell gate lines GTL1, GTL2, . . . , GTL8 may correspond to word lines, and a part of the memory cell gate lines GTL1, GTL2, . . . , GTL8 may correspond to dummy word lines. The ground selection transistor GST may be connected to the corresponding ground selection lines GSL1, GSL2, and GSL3. The string selection transistor SST may be connected to the corresponding bit lines BL1, BL2, and BL3, and the ground selection transistor GST may be connected to the common source line CSL. Each bit line BL1, BL2, and BL3 may be connected to the corresponding page buffers PB1, PB2, and PB3. Each page buffer PB1, PB2, and PB3 may be any one of the plurality of page buffers PB1 to PBn included in the page buffer 14 of FIG. 2.

A word line (e.g., WL1) of the same height may be commonly connected to the memory cell of the same height, and the ground selection lines GSL1, GSL2, and GSL3 and the string selection lines SSL1, SSL2, and SSL3 may be separated, respectively. In the drawing, the memory block BLK1 is shown as being connected to ten gate lines SSL, GTL1, GTL2, . . . , GTL8, GSL and three bit lines BL1, BL2, and BL3, but is not limited thereto.

FIG. 5 is circuit diagram showing examples of a cell string and a page buffer according to some implementations. In FIG. 5, the circuit diagram shows a connection relationship between a first_first cell string N11 among the plurality of cell strings NS11 to NS33 and a first page buffer PB1 in FIG. 4. Hereinafter, the description of the first_first cell string N11 may be applied to each plurality of cell strings, and the description of the first page buffer PB1 connected to the first_first cell string N11 may be applied to the corresponding page buffers PB1, PB2, and PB3.

In FIGS. 4 and 5, the first_first cell string N11 may be connected between the common source line CSL and the first bit line BL1. The first_first cell string N11 may be connected to the first page buffer PB1 through the first bit line BL1.

The first_first cell string N11 may be connected to the plurality of gate lines GTL. The first string selection transistor SST1 included in the first_first cell string N11, the plurality of memory cells MC1, MC2, . . . , MC8, and the first ground selection transistor GST1 may be connected to the first string selection line SSL1, the memory cell gate lines GTL1, GTL2, . . . , GTL8, and the first ground selection line GSL1.

One end of the first erase transistor T_ers1) can be connected to the common source line CSL. The first erase transistor T_ers1 may be turned on or turned off depending on the first erase control signal VG_ers1. According to some implementations, the first erase transistor T_ers1 may be an NMOS transistor, but it is not limited thereto.

During the erase operation, the first erase transistor T_ers1 may be turned on and provide the erase voltage through the common source line CSL.

According to some implementations, during the stress operation, the first erase transistor T_ers1 may be turned on and provide the first stress voltage Vst1 to the common source line CSL. According to some implementations, the first stress voltage Vst1 may be an erase voltage or a ground voltage. According to some implementations, the first erase transistor T_ers1 may be included in the row decoder 13 of FIG. 2, but it is not limited thereto.

The first page buffer PB1 may include a first bit line selection transistor T_SLT1, a second_first erase transistor T_ers21, a first data latch DL1, a first_first transistor T11, and a second_first transistor T21.

The first bit line selection transistor T_SLT1, and the second_first erase transistor T_ers21 may respectively correspond to the bit line selection transistor T_SLT and the second erase transistor T_ers2 of FIG. 3.

The first bit line selection transistor T_SLT1 may be placed between the first connection node N1 connected to the first bit line BL1and the first sensing node SO1. The first bit line selection transistor T_SLT1may be turned on or turned off depending on the bit line selection signal BLSLT.

One end of the second_first erase transistor T_ers21 may be connected to the first connection node N1 connected to the first bit line BL1. The second_first erase transistor T_ers21 may be turned on or turned off depending on the second erase control signal VG_ers2.

The first data latch DL1 may correspond to the data latch DL of FIG. 3, and it is obvious that the description of the data latch DL in 3 is applied to the first data latch DL1. According to some implementations, the first data latch DL1 may be operated as a sensing latch SL.

The first data latch DL1 may include a third_first transistor T31 and a fourth_first transistor T41. The third_first transistor T31 may include a gate terminal that receives a first data DATA1, a source terminal that receives a high voltage HV, and a drain terminal connected to the source terminal of the first_first transistor T11. According to some implementations, the high voltage HV may be the erase voltage of the non-volatile memory device 10. According to some implementations, the third_first transistor T31 may be a PMOS transistor, but is not limited thereto. The third_first transistor T31 may be turned on or turned off depending on the first data DATA1.

The fourth_first transistor T41 may include a gate terminal that receives the first data DATA1, a source terminal that receives the ground voltage, and a drain terminal connected to the source terminal of the second_first transistor T21. According to some implementations, the fourth_first transistor T41 may be an NMOS transistor, but it is not limited thereto. The fourth_first transistor T41 may be turned on or turned off depending on the first data DATA1.

The first_first transistor T11 may include a gate terminal that receives a bit line setup signal BLSU, a source terminal that receives the drain terminal of the third_first transistor T31, and a drain terminal connected to the first sensing node SO1. According to some implementations, the first_first transistor T11 may be a PMOS transistor, but it is not limited thereto. The first_first transistor T11 can be turned on or turned off depending on the bit line setup signal BLSU.

The second_first transistor T21 may include a gate terminal that receives a ground control signal SOGND, a source terminal that receives the drain terminal of the fourth_first transistor T41, and a drain terminal connected to the first sensing node SO1. According to some implementations, the second_first transistor T21 may be an NMOS transistor, but it is not limited thereto. The second_first transistor T21 may be turned on or turned off depending on the ground control signal SOGND.

During the erase operation, the second_first erase transistor T_ers21 may be turned on and provide the erase voltage to the first bit line BL1 through the first connection node N1.

According to some implementations, during the stress operation, the second_first erase transistor T_ers21 may be turned on and provide the second stress voltage Vst2 to the first bit line BL1 through the first connection node N1. According to some implementations, the second stress voltage Vst2 may be an erase voltage or a ground voltage. When the second_first erase transistor T_ers21 is turned on during the stress operation, the first bit line selection transistor T_SLT1 may be turned off.

According to some implementations, during the stress operation, the first bit line selection transistor T_SLT1 may be turned on, and based on the first data DATA1 latched in the first data latch DL1, the second stress voltage Vst2 may be provided to the first bit line BL1 through the first connection node N1. When the first bit line selection transistor T_SLT1 is turned on during the stress operation, the second_first erase transistor T_ers21 may be turned off.

For example, when the first bit line selection transistor T_SLT1 is turned on, the second_first erase transistor T_ers21 is turned off, the first_first and second_first transistors T11 and T21 are turned on, and the first data latch DL1 latches ‘1’ or a logic high as first data DATA1, the first bit line selection transistor T_SLT1 may be turned on and provide the second stress voltage Vst2 corresponding to the ground voltage to the first bit line BL1.

In FIGS. 4 and 5, the first page buffer PB1 is shown to include only the first bit line selection transistor T_SLT1, the second_first erase transistor T_ers21, and the first_first to fourth_first transistors T11 to T41, but according to some implementations, circuit elements may be additionally placed, and the connection relationship of the circuit elements may change depending on the additional placement.

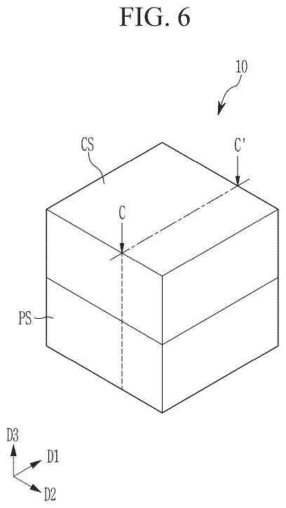

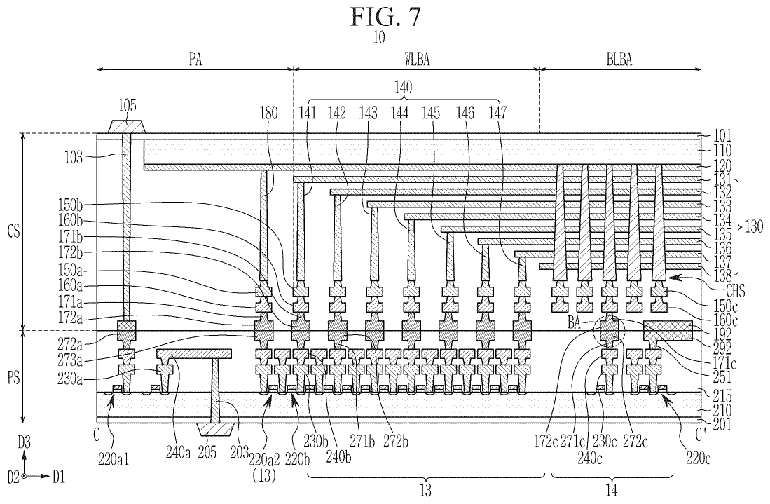

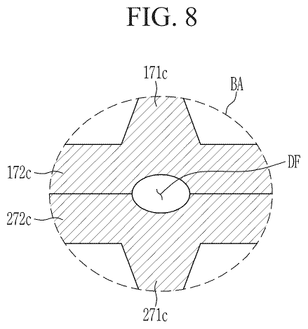

FIG. 6 is a perspective view showing an example of a non-volatile memory device according to some implementations. FIG. 7 is a cross-sectional view showing an example of a non-volatile memory device taken along a line C-C′ of FIG. 6 according to some implementations. FIG. 8 is an enlarged view of an example of a bonding area BA of FIG. 7 according to some implementations.

In FIG. 8, the non-volatile memory device 10 may be a chip to chip (C2C) structure. The non-volatile memory device 10 may include a cell array structure CS and a peripheral circuit structure PS. The cell array structure CS and the peripheral circuit structure PS are stacked in the third direction D3, and at least some of the cell array structure CS and the peripheral circuit structure PS may overlap each other in the third direction D3.

The cell array structure CS of the non-volatile memory device 10 may correspond to the memory cell circuit CC of FIG. 2, and the peripheral circuit structure PS may correspond to the peripheral circuit PC of FIG. 2. Each of the cell array structure CS and the peripheral circuit structure PS of the non-volatile memory device 10 may include an external pad bonding area PA, a word line bonding area WLBA, and a bit line bonding area BLBA.

The peripheral circuit structure PS may include a first substrate 210, an interlayer insulating layer 215, a plurality of circuit elements 220a1, 220a2, 220b, and 220c formed on the first substrate 210, a first metal layer 230a, 230b, and 230c respectively connected to the plurality of circuit elements 220a1, 220a2, 220b, and 220c, and a second metal layer 240a, 240b, and 240c formed on the first metal layer 230a, 230b, and 230c. In some implementations, the first metal layer 230a, 230b, and 230c may be formed of tungsten, which has a relatively high resistance, and the second metal layer 240a, 240b, and 240c may be formed of copper, which has a relatively low resistance.

In FIG. 7, only the first metal layer 230a, 230b, and 230c and the second metal layer 240a, 240b, and 240c are shown, but it is not limited thereto, at least one or more metal layers may be more formed on the second metal layer 240a, 240b, and 240c. At least some of one or more metal layers formed on the second metal layer 240a, 240b, and 240c may be formed of aluminum, etc., which has a lower resistance than copper that forms the second metal layers 240a, 240b, and 240c.

The interlayer insulating layer 215 may be placed on the first substrate 210 to cover the plurality of circuit elements 220a1, 220a2, 220b, and 220c, the first metal layer 230a, 230b, and 230c, and the second metal layer 240a, 240b, and 240c, and include an insulating material such as silicon oxide, silicon nitride, etc.

A lower bonding metal 271b and 272b may be formed on the second metal layer 240b of the word line bonding area WLBA. In the word line bonding area WLBA, the lower bonding metals 271b, and 272b of the peripheral circuit structure PS may be electrically connected to the upper bonding metals 271b, and 272b of the cell array structure CS to each other by a bonding method, and the lower bonding metal 271b, and 272b and the upper bonding metal 271b, and 272b may be formed of aluminum, copper, or tungsten.

The cell array structure CS may provide at least one memory block. The cell array structure CS may include a second substrate 110 and a common source line 120. On the second substrate 110, a plurality of conductive lines 131 to 138 and 130 may be formed along a direction (i.e., a third direction D3) perpendicular to the upper surface of the second substrate 110; and 130.

According to some implementations, the plurality of conductive line 130 may include string selection lines and ground selection lines disposed at the upper and lower portions, respectively, and a plurality of word lines may be disposed between the string selection line and the ground selection line. The plurality of conductive lines 130 may correspond to the plurality of gate lines GTL of FIGS. 4 and 5.

In the bit line bonding area BLBA, the channel structure CHS may extend in the third direction D3 vertical to the upper surface of the second substrate 110 and extend through the plurality of conductive line 130. The channel structure CHS may include a data storage layer, a channel layer, and an embedded insulating layer. According to some implementations, the memory cells, may be formed in the same form as the cell strings NS11 to NS33 of FIG. 4 along the channel structure CHS. The channel layer may be electrically connected to the first metal layer 150c and the second metal layer 160c. For example, the first metal layer 150c may be a bit line contact, and the second metal layer 160c may be the bit line BL described above in FIG. 2 to FIG. 5. According to some implementations, bit line 160c may extend along a second direction D2 parallel to the upper surface of the second substrate 110.

The area where the channel structure CHS and the bit line 160c are placed may be defined as the bit line bonding area BLBA. The bit line 160c may be electrically connected to the circuit elements 220c included in the page buffer 14 of the peripheral circuit structure PS in the bit line bonding area BLBA. For example, the bit line 160c may be connected to the upper bonding metal 171c and 172c of the cell array structure CS. Accordingly, page buffer 14 may be connected to the bit line 160c through the bonding metals 171c, 172c, 271c, and 272c. According to some implementations, at least some of the circuit elements 220c of the page buffer 14 may be placed to overlap the bonding metals 171c, 172c, 271c, and 272c in the third direction D3. According to some implementations, the page buffer 14 may correspond to the page buffer 14 above-described in FIGS. 2 to 5.

The circuit elements 220c placed in the bit line bonding area BLBA may provide the erase voltage to the bit line 16c0 through the bonding metals 171c, 172c, 271c, and 272c during the erase operation of the non-volatile memory device 10. According to some implementations, the circuit elements 220c disposed in the bit line bonding area BLBA may provide the stress voltage to the bit line 160c through the bonding metals 171c, 172c, 271c, and 272c during the stress operation of the non-volatile memory device 10. The circuit elements 220c may correspond to the second erase transistor T_ers2, the bit line selection transistor BLSLT, and the first_first to fourth_first transistors T11 to T41 of FIG. 3.

Also, the upper bonding metal 171c and 172c, in the bonding area BA where the cell array structure CS and the peripheral circuit structure PS is in contact, may be in contacted and electrically connected by a bonding method with the lower bonding metal 271c and 272c, which are connected to the circuit elements 220c of the page buffer 14.

According to some implementations, a defect (DF) may be placed between the upper bonding metal 171c and 172c and the lower bonding metal 271c and 272c. According to some implementations, the defect DF may be a void generated in the manufacturing process of the non-volatile memory device 10, a bridge due to a not open phenomenon, or a residue of an insulating material, but it is limited thereto. The defect DF may cause a progressive defect of the non-volatile memory device 10.

The defect DF in the bonding metals 171c, 172c, 271c, and 272c may increase the resistance of the bonding area BA, when a high voltage is applied to the bit line bonding area BLBA, the bonding area BA may be busted due to the increase in the resistance due to the defect DF, resulting in the defect DF within the bit line 160c.

As an example, the page buffer 14 may output the stress voltage in the bit line 160c direction. According to some implementations, the stress voltage applied to the bit line 160c direction may have the different voltage level from the stress voltage applied to the common source line 120. According to some implementations, the page buffer 14 may output an erase voltage or a ground voltage.

In the non-volatile memory device 10, according to some implementations, a stress voltage difference may be generated in the bonding area BA within the bit line bonding area BLBA, and the defect DF corresponding to the bit line 160c may be developed and detected early through the stress voltage difference.

In the word line bonding area WLBA, the plurality of conductive line 130 may extend along the first direction D1 parallel to the upper surface of the second substrate 110 and may be connected to the plurality of cell contact plug 141 to 147 and 140. The plurality of cell contact plug 140, at least some of which extend with the different lengths along the first direction D1, may be connected to the plurality of conductive line 130 in the pad area providing a landing point for the cell contact plug. The first metal layer 150b and the second metal layer 160b may be sequentially connected to the upper part of the plurality of cell contact plug 140 connected to the plurality of conductive line 130. The plurality of cell contact plug 140 may be connected to the peripheral circuit structure PS through the upper bonding metal 171b and 172b of the cell array structure CS and the lower bonding metal 271b, and 272b of the peripheral circuit structure PS in the word line bonding area WLBA.

The cell contact plug 140 may be electrically connected to the circuit elements 220b included in the row decoder 13 in the peripheral circuit structure PS. According to some implementations, the operating voltage of the circuit elements 220b providing the row decoder 13 may be different from the operating voltage of the circuit elements 220c providing the page buffer 14. For example, the operating voltage of the circuit elements 220c providing the page buffer 14 may be greater than the operating voltage of the circuit elements 220b providing the row decoder 13.

The common source line contact plug 180 may be placed in the external pad bonding area PA. The common source line contact plug 180 is made of a conductive material, such as a metal, a metal compound, or polysilicon, and may be electrically connected to the common source line 120. The first metal layer 150a and the second metal layer 160a may be sequentially stacked on the common source line contact plug 180. For example, the area that does not overlap with the plurality of conductive line 130 in the third direction D3 may be defined as the external pad bonding area PA.

The circuit elements 220a2 placed in the external pad bonding area PA may provide the erase voltage to the common source line 120 through the common source line contact plug 180 during the erase operation of the non-volatile memory device 10. According to some implementations, the circuit elements 220a2 disposed in the external pad bonding area PA may provide the stress voltage to the common source line 120 through the common source line contact plug 180 during the stress operation of the non-volatile memory device 10. The common source line 120 may correspond to the common source line CSL above-described in FIGS. 2 to 5.

According to some implementations, the circuit elements 220a2 that provide the erase voltage or the stress voltage may be included in the row decoder 13, and may correspond to the first erase transistor T_ers1 of FIG. 5. In FIG. 7, the circuit elements 220a2 that provide the erase voltage are shown to be placed in the external pad bonding area PA, but according to an embodiment, they may be placed in the word line bonding area WLBA.

Input/output pads 105 and 205 may be placed in the external pad bonding area PA. A lower insulation layer 201 covering the lower surface of the first substrate 210 may be formed under the first substrate 210, and a first input/output pad 205 may be formed on the lower insulation layer 201. The first input/output pad 205 may be connected to at least one of the plurality of circuit elements 220a, 220b, and 220c placed in the peripheral circuit structure PS through the first input/output contact plug 203, and be separated from the first substrate 210 by the lower insulation layer 201. Additionally, a side insulating layer may be disposed between the first input/output contact plug 203 and the first substrate 210 to electrically separate the first input/output contact plug 203 and the first substrate 210.

An upper insulation layer 101 may be formed on the second substrate 110 to cover the upper surface of the second substrate 110, and a second input/output pad 105 may be disposed on the upper insulation layer 101. The second input/output pad 105 may be connected to at least one of the plurality of circuit elements 220a, 220b, and 220c placed in the peripheral circuit structure PS through the second input/output contact plug 103.

According to some implementations, the second substrate 110 and the common source line 120 may not be placed in the area where the second input/output contact plug 103 is placed. Additionally, the second input/output pad 105 may be placed so as not to overlap with the plurality of conductive line 130 in the third direction D3. The second input/output contact plug 103 may be separated from the second substrate 110 in a direction parallel to the upper surface of the second substrate 110, and be connected to the second input/output pad 105 through the interlayer insulating layer of the cell array structure CS.

According to some implementations, the first input/output pad 205 and the second input/output pad 105 may be formed selectively. For example, the non-volatile memory device 10 may include only the first input/output pad 205 disposed on the first substrate 210, or may include only the second input/output pad 105 disposed on the second substrate 110. In some implementations, the non-volatile memory device 10 may include both the first input/output pad 205 and the second input/output pad 105.

In each of the external pad bonding area PA and the bit line bonding area BLBA included in each of the cell array structure CS and the peripheral circuit structure PS, the metal pattern of the uppermost metal layer may be present as a dummy pattern, or the uppermost metal layer may be empty.

In the external pad bonding area PA, corresponding to the lower metal pattern formed in the uppermost metal layer of the peripheral circuit structure PS, an upper metal pattern of the same type as the lower metal pattern of the peripheral circuit structure PS may be formed in the upper metal layer of the cell array structure CS.

Lower bonding metals 271b and 272b may be formed on the second metal layer 240b of the word line bonding area WLBA. In the word line bonding area WLBA, the lower bonding metals 271b and 272b of the peripheral circuit structure PS may be in contact with the upper bonding metals 171b and 172b of the cell array structure CS each other by a bonding method and be electrically connected.

Also, in the bit line bonding area BLBA, corresponding to the lower metal pattern 252 formed in the uppermost metal layer of the peripheral circuit structure PS, an upper metal pattern 192 of the same form as the lower metal pattern 252 may be formed in the uppermost metal layer of the cell array structure CS. The contact may not be formed on the upper metal pattern 192 formed in the uppermost metal layer of the cell array structure CS.

In some implementations, the control logic described in FIGS. 2 to 5 may be placed in the peripheral circuit structure PS. For example, the control logic may control the row decoder 13 and the page buffer 14 to apply the different stress voltages to both ends of the bit line bonding area BLBA.

FIG. 9 is a flowchart illustrating an example of an operation method of a non-volatile memory device according to some implementations.

In FIGS. 1, 2, and 9, the control logic 12 performs the stress operation for the memory cell array 11 (S110). The control logic 12 may output the voltage control signal CTRL_vol, the page buffer control signal CTRL_P, the row address X-ADDR, and the column address Y-ADDR and control the row decoder 13 and the page buffer 14 to apply the stress voltage Vst1 and Vst2 for the memory cell array 11.

According to some implementations, the control logic 12 may control the row decoder 13 and the page buffer 14 to apply the stress voltages Vst1 and Vst2 to the memory cell array 11 based on the control signal CTRL of the storage controller 20. According to some implementations, in an electrical die sorting (EDS) test process, without being limited to the example, the control logic 12 may control the row decoder 13 and the page buffer 14 so that the stress voltages Vst1 and Vst2 are applied to the memory cell array 11.

During the stress operation, the row decoder 13 may provide the first stress voltage Vst1 to the common source line CSL, and the page buffer 14 may provide the second stress voltage Vst2 to the bit line BL. During the stress operation, the row decoder 13 may apply the pass voltage Vpass to the plurality of string selection lines SSL, the plurality of word lines WL, and the plurality of ground selection lines GSL included in the selected memory blocks BLK1 to BLKz.

The voltage level of the first stress voltage Vst1 and the voltage level of the second stress voltage Vst2 may be different from each other. According to some implementations, the stress voltages Vst1 and Vst2 may be either erase voltage Vers or ground voltage, for example, if the first stress voltage Vst1 is the erase voltage Vers, the second stress voltage Vst2 may be the ground voltage, and if the second stress voltage Vst2 is the ground voltage, the second stress voltage Vst2 may be the erase voltage.

According to some implementations, as shown in FIGS. 7 and 8, if the defect DF is disposed between the bonding metals 171c, 172c, 271c, and 272c, based on the applied stress voltage Vst1 and Vst2, a high voltage is applied to the bonding metals 171c, 172c, 271c, and 272c so that a bursting phenomenon may occur in the bonding area BA of FIG. 7 and FIG. 8. Due to the above bursting phenomenon, a defect in the bit line BL may appear and a defect in the bit line BL may be detected.

According to some implementations, the stress operation may be performed by a unit of the memory blocks BLK1 to BLKz, but it is not limited thereto and may be performed by a unit of the bit line BL based on the data latched in the data latch (DL in FIG. 3) within the plurality of page buffers PB1 to PBn.

The control logic 12 performs a defect detection operation for each bit line BL (S120).

The defect detection circuit DD may provide the control signal to the plurality of page buffers PB1 to PBn and/or the row decoder 13 to detect defects in the bit line BL after the stress operation (S110). As an example, the defect detection circuit DD may generate control signals to control the plurality of page buffers PB1 to PBn and the row decoder 13 based on the different control timings.

The defect detection circuit DD may detect the defects for each bit line based on the different control timing. According to some implementations, the defect detection circuit DD may detect defects and malfunctions in the bit line caused by the stress operation.

The control logic 12 performs a repair operation based on the result of the defect detection operation (S130).

The repair unit RU may perform a repair operation for the bit line BL based on the detection result in the step (S120). When the defect detection circuit DD detects the defect or the malfunction for one bit line, the repair unit RU may perform a repair operation for the bit line and provide the page buffer control signal CTRL_P to the page buffer 14. Through the repair operation of the repair unit RU, the bit line that operates erroneously due to the defect may be replaced with a new bit line.

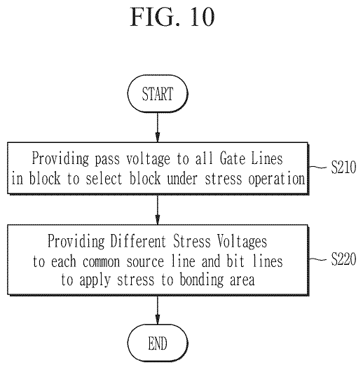

FIG. 10 is a flowchart illustrating an example of an operation method of a non-volatile memory device according to some implementations. The stress operation in the step (S110) of FIG. 9 may include the steps (S210) to (S220) of FIG. 10.

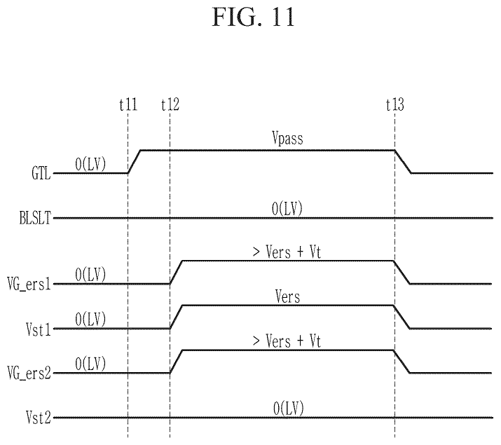

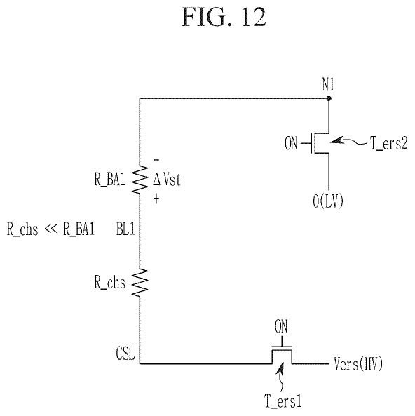

FIG. 11 is a timing diagram illustrating an example of an operation method of a non-volatile memory device according to some implementations. FIG. 12 is a circuit diagram showing examples of a cell string, a bit line, and a page buffer according to an operation of a non-volatile memory device according to some implementations.

In FIGS. 1 to 5, and 10, the row decoder 13 applies the pass voltage Vpass to the plurality of gate lines GTL within the selected memory block (S210).

Additionally, in FIGS. 11 and 12, the control logic 12 may provide the voltage control signal CTRL_vol and the row address X-ADDR to the row decoder 13 to apply the pass voltage Vpass to all plurality of gate lines GTL within the memory block.

At a time t11, the row decoder 13 may apply the pass voltage Vpass to all plurality of gate lines GTL in the selected memory block. According to some implementations, the plurality of gate lines GTL may include a string selection line SSL, memory cell gate lines GTL1, GTL2, . . . , GTL8, and a ground selection line GSL. According to some implementations, the pass voltage Vpass may be 2V to 7V, preferably 3V to 5V.

As the pass voltage Vpass for the gate line GTL is applied in the stress operation, the plurality of cell strings NS11 to NS33 within the memory block may each be modeled as a channel structure resistor R_chs.

Also, the bonding area BA of FIGS. 7 and 8 may be modeled as a bonding area resistor, for example, the bonding area BA connected to the first_first cell string NS11 may be modeled as a first bonding area resistor R_BA1.

If the defect DF of FIG. 8 is included in the bonding area BA connected to the first_first cell string NS11, the first bonding area resistor R_BA1 may be larger than the channel structure resistor R_chs. According to some implementations, the first bonding area resistor R_BA1 including the defect may have a channel structure resistor R_chs ratio of 100 or more, but is not limited thereto.

In response to the plurality of gate lines GTL being provided to the pass voltage Vpass, the row decoder 13 and the page buffer 14 provide the different stress voltages Vst1 and Vst2 to each common source line CSL and bit line BL, respectively (S220).

The first stress control voltage Vsc1 and the second stress control voltage Vsc2 generated in the voltage generator 15 may be provided to the row decoder 13 and the page buffer 14. Through the generated first stress control voltage Vsc1 and second stress control voltage Vsc2, the stress operation of the row decoder 13 and the page buffer 14 may be controlled.

At a time t12, the first erase transistor T_ers1 in row decoder 13 and the second erase transistor T_ers2 in the page buffer 14 may be turned on.

For example, a voltage exceeding the sum of the erase voltage Vers and the threshold voltage Vt of the first erase transistor T_ers1 is applied to the gate terminal of the first erase transistor T_ers1 as the first erase control signal VG_ers1, the first erase transistor T_ers1 may be turned on. In addition, a voltage exceeding the sum of the erase voltage Vers and the threshold voltage Vt of the second erase transistor T_ers2 is applied to the gate terminal of the second erase transistor T_ers2 as the second erase control signal VG_ers2, and then the second erase transistor T_ers may be turned on. According to some implementations, the erase voltage Vers may be 18V to 22V.

The row decoder 13 may provide a high voltage HV as a first stress voltage Vst1 to the common source line CSL. For example, the high voltage HV may be the erase voltage Vers. For example, the high voltage HV may be the erase voltage Vers.

The page buffer 14 may provide a low voltage LV as a second stress voltage Vst2 in the bit line BL direction. As an example, the page buffer 14 may provide the ground voltage to the first connection node N1 connected to the first bit line BL1.

From a time t12 to a time t13, the row decoder 13 may provide the high voltage HV as the first stress voltage Vst1 to the common source line CSL, and the page buffer 14 may provide the low voltage LV to the bit line BL as the second stress voltage Vst2. there is. Due to the provision of the first and second stress voltages Vst1 and Vst2, a stress voltage difference ΔVst may be applied to the first bonding area resistor R_BA1. According to some implementations, due to the stress voltage difference ΔVst, the bursting may occur for the bonding metals 171c, 172c, 271c, and 272c in the bonding area BA of FIG. 8.

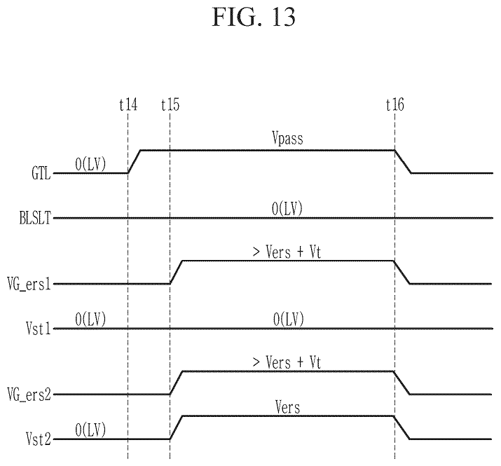

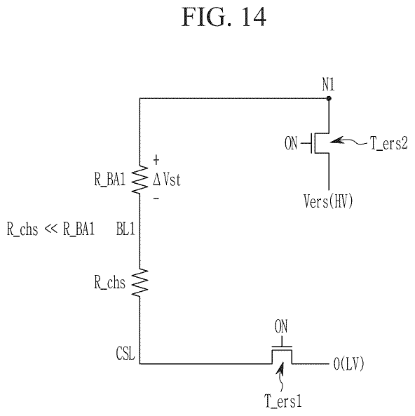

FIG. 13 is a timing diagram showing an example of an operation method of a non-volatile memory device according to some implementations. FIG. 14 is a circuit diagram showing examples of a cell string, a bit line, and a page buffer according to an operation of a non-volatile memory device according to some implementations.

According to some implementations, the operation of the non-volatile memory device described in FIGS. 11 and 12, and the operation of the non-volatile memory device described in FIGS. 13 and 14 may be performed differently by varying an operation time or an operation performance position. For case of explanation, the explanations in FIGS. 13 and 14 will focus on the differences from FIGS. 11 and 12.

In FIGS. 1 to 5, and 10, the row decoder 13 applies the pass voltage Vpass to the plurality of gate lines GTL in the selected memory block (S210).

Additional refereeing to FIGS. 13 and 14, the pass voltage Vpass may be applied to all plurality of gate lines GTL. At a time t14, the row decoder 13 may apply the pass voltage Vpass to all plurality of gate lines GTL in the selected memory block.

As the pass voltage Vpass for the gate line GTL is applied in the stress operation, likewise FIG. 12, the plurality of cell strings NS11 to NS33 in the memory block may be modeled as the channel structure resistor R_chs, and the bonding area BA of FIGS. 7 and 8 may be modeled as the bonding area resistor. For example, the bonding area BA connected to the first_first cell string NS11 may be modeled as the first bonding area resistor R_BA1.

In response to the plurality of gate lines GTL being provided with the pass voltage Vpass, the row decoder 13 and the page buffer 14 provide the different stress voltages Vst1 and Vst2 to each common source line CSL and bit line BL, respectively (S220).

The first stress control voltage Vsc1 and the second stress control voltage Vsc2 generated by voltage generator 15 may be provided to the row decoder 13 and the page buffer 14. Through the generated first stress control voltage Vsc1 and second stress control voltage Vsc2, the stress operations of the row decoder 13 and the page buffer 14 may be controlled.

At a time t15, the first erase transistor T_ers1 in the row decoder 13 and the second erase transistor T_ers2 in the page buffer 14 may be turned on.

The row decoder 13 may provide the low voltage LV as the first stress voltage Vst1 to the common source line CSL. The page buffer 14 may provide the high voltage HV as the second stress voltage Vst2 in the bit line BL direction. As an example, the page buffer 14 may provide the erase voltage Vers to the first connection node N1 connected to the first bit line BL1.

From a time t15 to a time t16, the row decoder 13 may provide the low voltage LV as the first stress voltage Vst1 to the common source line CSL, and page buffer 14 may provide the high voltage HV to the bit line BL as the second stress voltage Vst2. For example, the high voltage HV may be the erase voltage Vers and the low voltage LV may be the ground voltage.

Due to the provision of the first and second stress voltages Vst1 and Vst2, the stress voltage difference ΔVst may be applied to the first bonding area resistor R_BA1. According to some implementations, due to the stress voltage difference ΔVst in FIG. Burst may occur for bonding metals (171c, 172c, 271c, 272c) in bonding area BA of 8. According to some implementations, due to the stress voltage difference ΔVst, the bursting may occur for the bonding metals 171c, 172c, 271c, and 272c in the bonding area BA of FIG. 8.

The direction in which the stress voltage difference ΔVst is applied to the first bonding area resistor R_BA1 in FIG. 14, and the direction in which the stress voltage difference ΔVst is applied to the first bonding area resistor R_BA1 in FIG. 12 may be reversed.

Through the operation method described above, the non-volatile memory device 10, which has a 3-dimensional stacking structure, may detect the progressive defects in the bonding area early and prevent an unrestored data from occurring. The non-volatile memory device 10 according to the embodiment may detect the progressive defects that will occur in the bit line at an early stage.

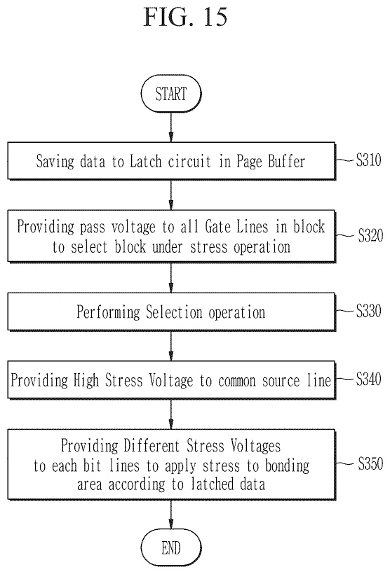

FIG. 15 is a flowchart illustrating an example of an operation method of a non-volatile memory device according to some implementations. According to some implementations, the stress operation in the step (S110) of FIG. 9 may include the steps (S310 to S350) of FIG. 15.

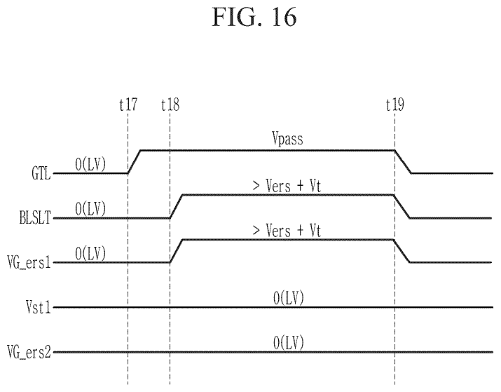

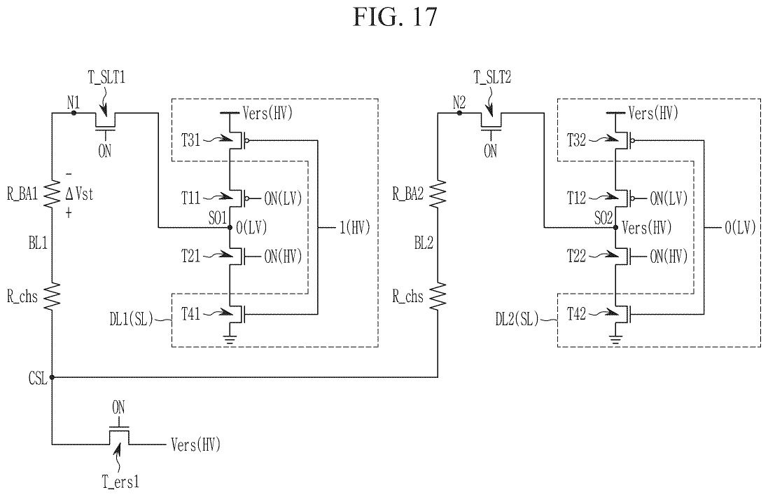

FIG. 16 is a timing diagram showing an example of an operation method of a non-volatile memory device according to some implementations. FIG. 17 is a circuit diagram showing examples of a cell string, a bit line, and a page buffer according to an operation of a non-volatile memory device according to some implementations.

In FIGS. 1 to 5, and 15, the control logic 12 stores a data in the latch circuit in the page buffer 14 (S310).

Before performing the stress operation, the control logic 12 may output the page buffer control signal CTRL_P and the column address Y-ADDR to latch the data DATA to the data latch DL in the page buffer PB. According to some implementations, based on the latched data DATA, the stress operation may be performed on the bit line BL connected to the data latch DL.

In FIG. 17, as an example, before performing the stress operation, the first data latch DL1 in first page buffer PB1 connected to first bit line BL1 may latch ‘1’ as a first data DATA1, and the second data latch DL2 in second page buffer PB2 connected to the second bit line BL2 may latch ‘0’ as a second data DATA2. According to some implementations, the latch operation may be performed before a time t17, which will be described below, but it is not limited thereto.

The row decoder 13 applies the pass voltage Vpass to the plurality of gate lines GTL in the selected memory block (S320).

Additionally referring to FIGS. 16 and 17, the control logic 12 may provide the voltage control signal CTRL_vol and the row address X-ADDR to the row decoder 13 to apply the pass voltage Vpass to all plurality of gate lines GTL in the memory block.

At a time t17, the row decoder 13 may apply the pass voltage Vpass to all plurality of gate lines GTL in the selected memory block.

In the stress operation, as the pass voltage Vpass is applied to the gate line GTL, the plurality of cell strings NS11 to NS33 in the memory block may be modeled as the channel structure resistor R_chs, respectively.

Also, the bonding area BA of FIGS. 7 and 8 may be modeled as the bonding area resistor, for example, the bonding area BA connected to the first_first cell string NS11 may be modeled as the first bonding area resistor R_BA1, and the bonding area BA connected to the second_first cell string NS21 may be modeled as the second bonding area resistor R_BA2.

If the defect DF of FIG. 8 is included in the bonding area BA connected to the first_first cell string NS11, the first bonding area resistor R_BA1 may be larger than the channel structure resistor R_chs. If the defect DF of FIG. 8 is not included in the bonding area BA connected to the first_first cell string NS11, according to an embodiment, the channel structure resistor R_chs may be larger than or equal to the second bonding area resistor R_BA2, but it is not limited thereto.

In response to the pass voltage Vpass being provided to the plurality of gate lines GTL, the control logic 12 performs the selection operation (S330).

In the selection operation (S330, the first stress control voltage Vsc1 and the second stress control voltage Vsc2 generated from the voltage generator 15 may be provided to the row decoder 13 and the page buffer 14. Through the generated first stress control voltage Vsc1 and second stress control voltage Vsc2, the stress operations of the row decoder 13 and the page buffer 14 may be controlled.

At a time t18, the first bit line selection transistor T_SLT1 and the second bit line selection transistor T_SLT2 may be turned on.

For example, a voltage exceeding the sum of the erase voltage Vers and the threshold voltage Vt of the first and second bit line selection transistors T_SLT1 and T_SLT2 as a bit line selection signal BLSLT is applied to the gate terminals of the first bit line selection transistor T_SLT1 and the second bit line selection transistor T_SLT2 so that the first bit line selection transistor T_SLT1 and the second bit line selection transistor T_SLT2 may be turned on. Additionally, the low voltage LV is applied to the gate terminal of the second erase transistor T_ers2 as the second erase control signal VG_ers2, so that the second erase transistor T_ers2 may be turned off.

In addition, the low voltage LV may be input to a bit line setup signal BLSU to turn on the first_first transistor T11 and the first_second transistor T12, and the high voltage HV may be input to a ground control signal SOGND to turn on the second_first transistor T21 and the second_second transistor T22.

In response to the pass voltage Vpass being provided to the plurality of gate lines GTL, the row decoder 13 provides the high voltage HV as the first stress voltage Vst1 to the common source line CSL (S340).

At a time t18, the first erase transistor T_ers1 in the row decoder 13 may be turned on.

For example, a voltage exceeding the sum of the erase voltage Vers and the threshold voltage Vt of first erase transistor T_ers1 may be applied to the gate terminal of the first erase transistor T_ers1 so that the first erase control signal VG_ers1 may be turned on

The row decoder 13 may provide the high voltage HV as the first stress voltage Vst1 to the common source line CSL. For example, the high voltage HV may be the erase voltage Vers.

In response to the pass voltage Vpass being provided to the plurality of gate lines GTL, the page buffer 14 provides the second stress voltage Vst2 that is different from the first stress voltage Vst1 for each bit line based on the latched data (S350).

The page buffer 14 may provide the low voltage LV as the second stress voltage Vst2 based on the data latched in the data latch DL connected to the bit line BL.

For example, in FIG. 17, ‘1’ may be latched as the first data DATA1 in the first data latch DL1, and ‘0’ may be latched as the second data (DATA2) in the second data latch DL2. Based on first data DATA1, the low voltage LV may be provided as the second stress voltage Vst2 to the first connection node N1 connected to the first bit line BL1, and based on second data DATA2, the high voltage HV may be applied to the first connection node N1 connected to the second bit line BL2. For example, the high voltage HV may be the erase voltage Vers and the low voltage LV may be the ground voltage.

From a time t18 to a time t19, the row decoder 13 may provide the high voltage HV to the common source line CSL as the first stress voltage Vst1, the page buffer 14 may provide the low voltage LV to the first bit line BL1 as the second stress voltage Vst2, and the high voltage HV to the second bit line BL2.

Due to the selective provision of the second stress voltage Vst2 for each bit line, the stress voltage difference ΔVst may be applied to the first bonding area resistor R_BA1, and the stress voltage difference may be not applied to the second bonding area resistor R_BA2.

According to some implementations, the bursting may occur for the bonding metals 171c, 172c, 271c, and 272c in the bonding area BA of FIG. 8 connected to the first_first cell string NS11 due to the stress voltage difference ΔVst.

In FIG. 15, the step S330 to the step S350 are shown separately, but according to some implementations, the step S330 to the step S350 may be performed simultaneously.

The stress operation may be selectively performed for each bit line BL through the latched data of the data latch DL in the page buffer 14. Through the above-described operation method, the non-volatile memory device 10 with the 3-dimensional stacking structure may detect the progressive defects in the bonding area early and prevent the unrestored data from occurring. The non-volatile memory device 10 according to some implementations may selectively and early detect the progressive defects that will occur in the bit line.

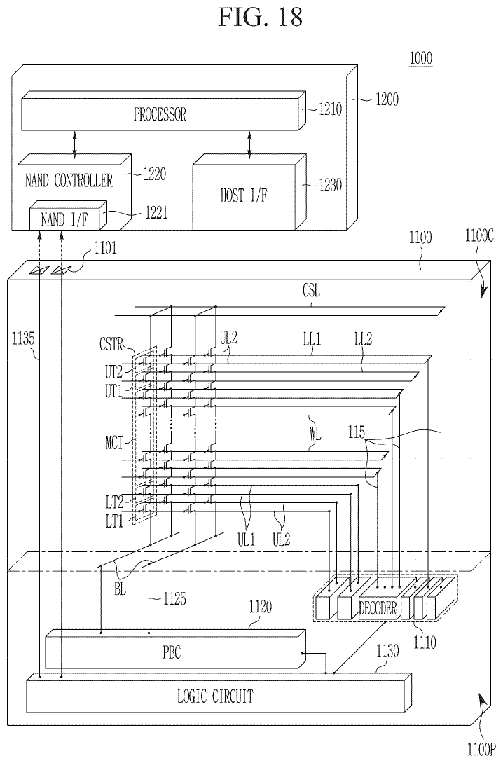

FIG. 18 is a block diagram showing an example of an electron system including a non-volatile memory device according to some implementations. In FIG. 18, an electron system 1000 may include a semiconductor device 1100 and a controller 1200 electrically connected to the semiconductor device 1100. The electron system 1000 may be a storage device including one or a plurality of semiconductor devices 1100 or an electronic device including the same. For example, the electron system 1000 may be a solid state drive (SSD) device, a universal serial bus (USB), a computing system, a medical device, or a communication device, including one or plurality of semiconductor devices 1100.

The semiconductor device 1100 may be a memory device, for example, referring to FIG. 2, may be the non-volatile memory device 10 according to the above-described embodiments of the present disclosure. The semiconductor device 1100 may include a first structure 1100P and a second structure 1100C on the first structure 1100P. The first structure 1100P may be a peripheral circuit structure including a row decoder circuit 1110, a page buffer circuit 1120, and a control logic circuit 1130. The second structure 1100C may be a memory cell structure including a plurality of bit lines BL, a common source line CSL, a plurality of word lines WL, first and second upper gate lines UL1 and UL2, first and second lower gate lines LL1 and LL2, and a memory cell string CSTR between the plurality of bit line BL and the common source line CSL. The plurality of word line WL, the first and second upper gate line UL1, and UL2, first and second lower gate line LL1 and LL2 may be the plurality of gate lines GTL described in FIG. 4 and FIG. 5.

In the second structure 1100C, each memory cell string CSTR may include lower transistors LT1 and LT2 adjacent to the common source line CSL, upper transistors UT1 and UT2 adjacent to the bit line BL, and a plurality of memory cell transistors MCT placed between the lower transistors LT1 and LT2 and the upper transistors UT1 and UT2. The number of lower transistors LT1 and LT2 and the number of upper transistors UT1 and UT2 may vary depending on some implementations.

According to some implementations, the upper transistors UT1 and UT2 may include string selection transistors, and the lower transistors LT1 and LT2 may include ground selection transistors. The lower gate lines LL1 and LL2 may be the gate electrodes of the lower transistors LT1 and LT2, respectively. The word line WL may be the gate electrodes of the memory cell transistor MCT, and the upper gate lines UL1 and UL2 may be the gate electrodes of the upper transistors UT1 and UT2, respectively.

According to some implementations, the lower transistors LT1 and LT2 may include a ground selection transistor LT2 connected in series. The upper transistors UT1 and UT2 may include a string selection transistor UT1 connected in series.

The common source line CSL, the first and second lower gate lines LL1 and LL2, the word line WL, and the first and second upper gate lines UL1 and UL2 may be electrically connected to the row decoder circuit 1110 through a first connection wire 1115 extending from the inside of the first structure 1100P to the second structure 1100C. The bit line BL may be electrically connected to the page buffer circuit 1120 through a second connection wire 1125 which extends from the first structure 1100P to the second structure 1100C. According to some implementations, the second connection wire 1125 may include the bonding area BA of FIG. 7 and FIG. 8.

In the first structure 1100P, the row decoder circuit 1110 and the page buffer circuit 1120 perform the control operations for at least one selected memory cell transistor among the plurality of memory cell transistor MCT. The row decoder circuit 1110 and the page buffer circuit 1120 may perform the stress operation described above in FIGS. 1 to 17. The row decoder circuit 1110 and the page buffer circuit 1120 may be controlled by the control logic circuit 1130. The semiconductor device 1100, through the stress operation described above in FIGS. 1 to 17, may detect the defects causing the progressive defects included in the second connection wire 1125 early.

The semiconductor device 1100 may communicate with the controller 1200 through the input/output pad 1101, which is electrically connected to the control logic circuit 1130. The input/output pad 1101 may be electrically connected to the control logic circuit 1130 through the input/output connection wire 1135 that extends from the inside of the first structure 1100P to the second structure 1100C.

The controller 1200 may include a processor 1210, a NAND controller 1220, and a host interface 1230. According to some implementations, the electron system 1000 may include a plurality of semiconductor devices 1100, and in this case, the controller 1200 may control the plurality of semiconductor devices 1100.

The processor 1210 may control the overall operation of the electron system 1000, including the controller 1200. The processor 1210 may operate according to a predetermined firmware and may access the semiconductor device 1100 by controlling the NAND controller 1220. The NAND controller 1220 may include a NAND interface 1221 that processes the communication with the semiconductor device 1100. Through the NAND interface 1221, control instructions for controlling the semiconductor device 1100, data to be written to the memory cell transistor MCT of the semiconductor device 1100, data to be read from the memory cell transistor MCT of the semiconductor device 1100, etc. may be transmitted. The host interface 1230 may provide a communication function between the electron system 1000 and an external host. When receiving the control instruction from the external host through the host interface 1230, the processor 1210 may control the semiconductor device 1100 in response to the control instruction.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A 3-dimensional semiconductor memory device comprising:
a cell array structure including
a first substrate,
a common source line disposed on the first substrate,
a plurality of conductive lines stacked in a first direction vertical to an upper surface of the first substrate on the common source line,
a channel structure extending through the plurality of conductive lines and connected to the common source line,
a bit line connected to the channel structure, and
a first bonding metal electrically connected to the bit line; and
a peripheral circuit structure including
a second bonding metal in contact with the first bonding metal,
a page buffer configured to provide a first stress voltage to the bit line through the second bonding metal in response to a pass voltage being applied to the plurality of conductive lines, and
a row decoder configured to provide a second stress voltage with a different voltage level from the first stress voltage to the common source line in response to providing the first stress voltage.

2. The 3-dimensional semiconductor memory device of claim 1,
wherein the plurality of conductive lines includes a lower conductive line disposed closest to the first substrate, an upper conductive line disposed furthest from the first substrate, and a plurality of middle conductive lines disposed between the lower conductive line and the upper conductive line, and,
wherein the page buffer is configured to apply the first stress voltage to the bit line in response to the pass voltage being applied to the upper conductive line, the lower conductive line, and the plurality of middle conductive lines.

3. The 3-dimensional semiconductor memory device of claim 2, wherein the pass voltage is 2V to 7V.

4. The 3-dimensional semiconductor memory device of claim 1, wherein one of the first stress voltage or the second stress voltage is an erase voltage, and the other one of the first stress voltage or the second stress voltage is a ground voltage.

5. The 3-dimensional semiconductor memory device of claim 4, wherein the page buffer is configured to, in response to application of the pass voltage, provide the erase voltage to the bit line and the row decoder is configured to provide the ground voltage to the common source line.

6. The 3-dimensional semiconductor memory device of claim 5,
wherein the page buffer includes (i) a first erase transistor that is connected to the bit line and is configured to provide an erase voltage to the bit line and (ii) a bit line selection transistor that is connected between the bit line and a sensing node,
wherein the row decoder includes a second erase transistor that is connected to the common source line and the second erase transistor is configured to provide an erase voltage to the common source line.

7. The 3-dimensional semiconductor memory device of claim 6, wherein the first erase transistor is configured to, in response to the application of the pass voltage, be turned on to provide the erase voltage to the bit line,
wherein the second erase transistor is configured to, in response to the application of the pass voltage, be turned on to provide the ground voltage to the common source line, and
wherein the bit line selection transistor is configured to, in response to the application of the pass voltage, be turned off.

8. The 3-dimensional semiconductor memory device of claim 4, wherein the page buffer is configured to, in response to the application of the pass voltage, provide a ground voltage to the bit line, and
wherein the row decoder is configured to, in response to the application of the pass voltage, provide an erase voltage to the common source line.

9. The 3-dimensional semiconductor memory device of claim 4, wherein the erase voltage is 18V to 22V.

10. The 3-dimensional semiconductor memory device of claim 1, wherein at least one of a void or an insulating material is placed between the first bonding metal and the second bonding metal.

11. The 3-dimensional semiconductor memory device of claim 10, wherein a first resistance for the first bonding metal and the second bonding metal is greater than a second resistance for the channel structure due to the application of the pass voltage.

12. The 3-dimensional semiconductor memory device of claim 11, wherein the peripheral circuit structure further includes control logic comprising:
a defect detection circuit configured to detect a result of a stress operation by the first and second stress voltage; and
a repair unit configured to perform a repair operation for each bit line based on the result of the stress operation.

13. The 3-dimensional semiconductor memory device of claim 10, wherein at least part of the page buffer is placed to overlap with the first and second bonding metals in the first direction.

14. A 3-dimensional semiconductor memory device comprising:
a memory cell array including a plurality of cell strings, a first cell string of the plurality of cell strings includes a plurality of first memory cells connected to a first bit line and a second cell string of the plurality of cell strings includes a plurality of second memory cells connected to a second bit line different from the first bit line, and a common source line connected to the first cell string and the second cell string;
a row decoder configured to apply an erase voltage to the common source line; and
a page buffer configured to apply an erase voltage to the first bit line and a ground voltage to the second bit line in response to the application of the erase voltage to the common source line.

15. The 3-dimensional semiconductor memory device of claim 14, wherein: the page buffer includes:
a first page buffer including a first data latch configured to store a first data provided to the first bit line, and a first bit line selection transistor between the first data latch and the first bit line, and
a second page buffer including a second data latch configured to store a second data provided to the second bit line, and a second bit line selection transistor between the second data latch and the second bit line.

16. The 3-dimensional semiconductor memory device of claim 15, wherein, in response to the application of the erase voltage to the common source line, the first page buffer is configured to provide the erase voltage to the first bit line based on the first data, and the second page buffer is configured to provide the ground voltage to the second bit line based on the second data.

17. The 3-dimensional semiconductor memory device of claim 14, wherein, in response to the application of the erase voltage to the common source line, a pass voltage is applied to a gate of the plurality of first memory cells and the gate of the plurality of second memory cells.

18. An operation method of a 3-dimensional semiconductor device comprising:
applying a pass voltage to a plurality of gate lines stacked in a vertical direction to an upper surface of a substrate;
applying a first stress voltage to a common source line extending between the substrate and the plurality of gate lines, and applying a second stress voltage, different from the first stress voltage, to a bit line connected to a channel structure that extends through the plurality of gate lines in response to the application of the pass voltage;
detecting defects for each bit line after applying the first stress voltage and the second stress voltage; and
performing a repair operation based on a result of the detecting defects.

19. The operation method of the 3-dimensional semiconductor device of claim 18,
wherein the plurality of gate lines includes a lower gate line placed closest to the substrate, an upper gate line placed furthest from the substrate, and a plurality of middle gate lines placed between the lower gate line and the upper gate line, and
wherein the applying the pass voltage for the plurality of gate lines includes applying the pass voltage to the lower gate line, the upper gate line, and the plurality of middle gate lines.

20. The operation method of the 3-dimensional semiconductor device of claim 18, further comprising:
storing data provided on the bit line to a data latch before applying the pass voltage, and
wherein the applying the second stress voltage to the bit line includes applying the second stress voltage to the bit line based on the data stored in the data latch.
